(19) United States
(12) Patent Application Publication
(10) Pub. No.: US 2025/0314919 A1
(43) Pub. Date: Oct. 9, 2025

(54) OPTICAL ISOLATOR FOR HIGH AVERAGE POWER AND HIGH PULSE ENERGY LASERS

(71) Applicants: Jan Vetrovec, Larkspur, CO (US); David M. Filgas, Newbury Park, CA (US); Sura Jottu Thiagarajan, Aurora, CO (US)

(72) Inventors: Jan Vetrovec, Larkspur, CO (US); David M. Filgas, Newbury Park, CA (US); Sura Jottu Thiagarajan, Aurora, CO (US)

(73) Assignee: Aqwest LLC, Larkspur, CO (US)

(21) Appl. No.: 18/831,282

(22) Filed: Oct. 12, 2024

Related U.S. Application Data
(60) Provisional application No. 63/629,359, filed on Oct. 13, 2023.
(60) Provisional application No. 63/731,410, filed on Apr. 29, 2024.

(51) Int. Cl. G02F 1/09; H01S 3/00

(52) U.S. Cl. CPC G02F 1/093; H01S 3/0064

(57) ABSTRACT

The present invention provides an optical isolator capable of operating with high-average power and high pulse energy laser beams especially at wavelengths near 2 μm. The inventive optical isolator generally comprises a Faraday optic formed as a relatively thin member with a relatively large size optical aperture having one large surface adapted to receiving an optical beam and second large surface adapted for heat removal for active cooling by gas or liquid. This arrangement provides heat conduction in a generally parallel to the path of the incident beam through the Faraday optics, therefore, thermo-optical effects are much reduced. A thermoelectric cooler may be provided between the thermally conductive member and the heat sink to allow for temperature control of the Faraday optic. This approach enables a convenient control of the actual rotation angle delivered by the Faraday optic and may be used to optimize optical isolation. Temperature control of the Faraday optic to a given set point may be automated by a closed loop circuit involving temperature sensing and TEC current control. A beam expanding telescope is provided to convert the collimated beam with a circular footprint to a collimated beam with an elliptical footprint of a larger area. Enlarging the beam footprint beneficially reduces intensity of the beam, which reduces the likelihood of optical damage. The inventive optical isolator may be practiced with polarized or unpolarized laser beams.

### PRIORITY

This patent application claims priority from U.S. provisional patent applications U.S. Ser. No. 63/629,359, filed on Oct. 13, 2023 and U.S. Ser. No. 63/731,410, filed on Apr. 29, 2024; each entitled “Optical Isolator for High-Average Power and High Pulse Energy Lasers” the entire contents of all of which are hereby expressly incorporated by reference.

### GOVERNMENT RIGHTS IN THIS INVENTION

Not applicable.

### FIELD OF THE INVENTION

This invention relates generally to optical isolators for lasers operating at high average power and high pulse energies.

### BACKGROUND OF THE INVENTION

Optical isolators are key elements that protect laser beamline components especially in laser systems involving laser oscillators and laser amplifiers.

An optical isolator (OI) is an optical diode allowing the transmission of light in only one direction. OIs are used to de-couple laser gain elements from backward propagating radiation caused by noise, backscatter, and/or reflections from laser beamline components and/or work surface. Feedback from backward propagating radiation may drive power instabilities and noise in laser oscillators and/or amplifiers, which may lead to catastrophic optical damage to beamline components. Therefore, one of more OIs are used in laser systems to block such backward propagating light and protect the laser beamline components.

In an OI, the non-reciprocal nature of the Faraday effect causes the plane of linear polarization in the backward propagating direction to be rotated an additional 45 degrees resulting in a polarization state which is rotated at 90 degrees to the transmission axis of the input polarizer. This arrangement allows passage of the forward propagating radiation with low transmission losses but it causes high transmission losses to backward propagating radiation. Prior art discloses OI suitable for isolation in polarized laser beamlines. Such devices are known as polarization maintaining (PM) OI. See, for example, U.S. Pat. No. 3,523,718. Prior art also discloses OI suitable for isolation in unpolarized laser beamlines. Such devices are known as polarization independent (PI) OI. See, for example, U.S. Pat. No. 4,178,073.

One current trend in the development of laser devices and their applications is toward pulsed lasers operating at high-average power and with high pulse energies. Such lasers may include the ultra-fast lasers (ULF) also known as ultrashort-pulse lasers (USPL). In such devices, the deleterious effects of backward propagating radiation may become even more pronounced. To answer this challenge, a number of prospective OIs are now in development or becoming commercially available for lasers operating near the commonly used 1 micrometer (μm) wavelength. Another current industry trend is toward eye-safer lasers operating in the vicinity of the 2 μm wavelength (generally in the range of 1.90 to 2.15 μm). These emerging eye-safer lasers are largely based on a trivalent thulium ion (Tm³⁺), which may be doped into a variety of host materials. Thulium-doped glass is typically used in fiber lasers. Thulium-doped single-crystals or polycrystalline (ceramic) materials are typically used in lasers as bulk type laser gain medium with large optical aperture. Both fiber and bulk type lasers are now being scaled to higher-average power and higher pulse energies. The development of suitable OI must overcome a number of challenges, which are substantially unique to the high-average power and high pulse energy lasers operating at near 2 μm wavelength including 1) Limited availability of suitable optically active materials, 2) Management of waste heat load due to partial absorption of laser light in the OI, 3) Susceptibility to laser-induced damage due to high-pulse energies and high-peak power, and (for fiber lasers) 4) Non-polarized (random polarization) nature of the laser light.

Main components of OIs typically include a Faraday rotator (FR) and associated laser light polarizing elements. An FR is typically comprised of a non-reciprocal, Faraday optical element (Faraday optic) and a magnet structure. The Faraday optic is immersed in magnetic field provided by the magnet structure and it is aligned with the laser beam so that the beam plane of polarization is rotated by 45 degrees upon one or more passages though the optics. The magnetic field inside the Faraday optic is generally parallel to the laser axis. The Faraday effect rotates the plane of linear polarization as the beam passes through the Faraday optic. The angle of rotation, θ, is given as θ(λ,T)=v(T,λ)·B(T)·L, where v(T,λ) is the Verdet constant of the Faraday optic, λ is the operating wavelength, T is temperature, B(T) is the magnetic flux density, and L is the Faraday optic length. The desirable characteristics in a Faraday rotator include a high Verdet constant, low light absorption coefficient at the targeted wavelength, low non-linear refractive index, and high laser damage threshold. Also, to curb thermally-caused effects, the Faraday optic should be as short as possible.

Polarization independent OI of prior art were primarily developed for telecommunication applications where optical beams are used at only low average power. Such OIs are passively cooled, which is sufficient under these operating conditions. In particular, waste heat due to laser light absorption is conducted radially through the Faraday optic, transferred into the FR mount, and dissipated into air or conducted to the optical table on which the FR is mounted. As the average power of the laser beam is increased, the waste heat load to the Faraday optic grows, the temperature of the optics rises, the Verdet constant changes, the OI is detuned from its nominal operating point, and its isolation is compromised. In addition, the temperature difference between the center of the beam and beam edge become more pronounced. This causes thermo-optical errors also known as thermal lensing. In addition, different level of isolation is attained at the beam center than at the edges because the Verdet constant is temperature sensitive.

A typical polarization independent OI 10 of prior art (see, for example U.S. Patent Application Publication 2018/0156976) shown in FIG. 1 comprises a Faraday optic 12 and a half-wave plate 26 positioned between two birefringent wedges (or plates) 16 and 18. The path of unpolarized laser input light 24 traveling in the forward direction passes through the first birefringent plate 16, Faraday optic 12, half-wave plate 26, and a second birefringent plate 18. In particular, a beam of unpolarized light 24 incident on the birefringent crystals 16 is first separated into an ordinary beam 24o and an extraordinary beam 24e having their respective planes of polarization at 90 degrees from each other. Beams 24o and 24e are directed through the Faraday optic 12, which causes their polarization planes to be rotated by 45 degrees. Beams 24o′ and 24e′ having rotated polarization planes and departing from the Faraday optic 12 now pass through the half-wave plate 26, which causes their polarization planes to be rotated by additional 45 degrees in the same direction as in the Faraday optic. As a result, the polarization planes of beams 24o″ and 24e″ exiting the halfwave plate 26 are rotated by a total of 90 degrees each compared to the respective original beams 24o and 24e. The beams 24o″ and 24e″ are directed through the second birefringent crystal 18 where they are recombined and exit the OI 10 as an unpolarized beam 24′″.

FIG. 2 shows the path of unpolarized light 34 traveling through the OI 10 in the backward direction. Incident unpolarized light 34′″ travelling backwards passes first through the birefringent crystal 18 and its is hereby separated into a beam 34o″ having an ordinary polarization and a beam 34e″ having an extraordinary polarization. Next, the respective polarization planes of the beams 34o″ and 34e″ are rotated 45 degrees by the half-wave plate 26. The resulting beams 34o′ and 34e′ are then rotated by the Faraday optic 12 by 45 degrees opposite to the direction of rotation acquired in the half-wave plate 26. Thus, the polarization directions of resulting beams 34o and 34e is same as for the respective beams 34o″ and 34e″. The reason is that the half-wave plate rotates the polarization plane relative to the direction of propagation, while the FR rotates the polarization plane relative to the direction of magnetization. Consequently, the beams 34o and 34e cannot be recombined into one in the birefringent wedge 16, but instead continue on as separate beams. Note that at this location, the backward propagating light is not collinear with the laser input beam 24 and, therefore, it can be easily separated and neutralized.

Most Faraday optic materials exhibit some absorption of light at their operating wavelength. Absorbed light turns into waste heat, which is deposited inside the Faraday optic. For operation at high-average power, this waste heat that must be effectively removed from the Faraday optic to avoid excessive temperature rise and a consequential change to the Verdet constant. Conduction of waste heat from within the Faraday optic to the surface from which the heat can be removed causes temperature gradients within the Faraday optic material. Such gradients may lead to thermo-mechanical distortions, thermal lensing, and thermally induced stresses. These effects contribute to depolarization and wavefront distortions in the incident laser beam.

Traditional Faraday optic is configured as a rod with cooled perimeter (see, e.g., U.S. Pat. Nos. 5,528,415 and 7,206,116). This configuration is susceptible to deleterious thermal gradients in the radial direction (i.e., generally perpendicular to the optical axis). Because the Verdet constant V(λ,T) is temperature dependent, such a thermal gradient may cause the polarization rotation to vary across the beam profile. The radial temperature profile also contributes to two other deleterious effects: thermal lensing and thermal birefringence. The former is primarily caused by the change in the Faraday optic refractive index with temperature (dn/dT). The latter is caused by the thermal strains via the photoelastic effect. Thermal birefringence may exceed polarizer extinction as the limiting factor determining the isolation ratio, and consequently, the effectiveness of an OI at high-average power.

Possible mitigations of the deleterious thermal effects may include: 1) Alignment of the temperature gradient with the optical axis, and 2) Reduction of the optical path necessary for the 45 degrees rotation. The former may be attained with the active mirror configuration disclosed for example by Tidwell in U.S. Pat. No. 5,115,340. The latter can may be attained by choosing a material with high Verdet constant and/or by increasing the magnetic field strength.

In summary, the shortfalls of OI of prior art that must be overcome include:
1) Operation limited to low-average power laser beams especially at wavelengths near 2 μm.
2) Operation at wavelengths near 2 μm limited to modest pulse energies.
3) Small size optical aperture, which translates to increased laser intensity and susceptibility to optical damage.

### SUMMARY OF THE INVENTION

The present invention provides an optical isolator (OI) capable of operating with high-average power and high pulse energy laser beams especially at wavelengths near 2 μm. The inventive OI offers large size optical aperture, which translates to increased robustness to optical damage. The OI includes active cooling and temperature tuning to attain very high isolation with low insertion loss.

The present invention provides an optical isolator (OI) capable of operating with laser beams having high-average power and high pulse energy especially at wavelengths near 2 μm. The inventive OI offers large size optical aperture, which translates to increased robustness to optical damage. The OI includes active cooling and temperature tuning to attain very high isolation with low insertion loss.

The inventive OI generally comprises a Faraday rotator (FR), polarization optic, input optics assembly, and output optics assembly. The FR further comprises a Faraday optic, magnet structure, and a thermally conductive member. The Faraday optics is made of a suitable magneto-optical material and it is formed as a thin member having a thickness, first large surface adapted to receiving an optical beam, and a second large surface. The second large surface has a high-reflectivity coating and it is attached to the thermally conductive member. In some aspects of the invention, the Faraday optic may be formed as a relatively thin film deposited on a substrate. The Faraday optics is immersed in magnetic field provided by the magnet structure. Preferably, the Faraday optic is magnetically saturable. In such a case, the magnetic field should be arranged to magnetically saturate the Faraday optic, at least in the zone irradiated by the laser beam. An incident optical beam makes a roundtrip through the Faraday optic by entering the first large surface, passing through the optic to the second surface, being reflected by the high-reflectivity coating, and passing through the optic back to the first surface. Preferably, the magnet structure and the Faraday optic are arranged so that the polarization plane of an incident beam is rotated by 45 degrees upon a round trip through the Faraday optic. Waste heat due to partial absorption of the incident laser beam is conducted through the Faraday optic material to the second surface and transferred to the thermally conductive member. Because the direction in which the heat is conducted is generally parallel to the path of the incident beam through the Faraday optics, thermo-optical effects are much reduced. The thermally conductive member may be arranged to transfer the waste heat to an air-cooled or liquid-cooled heat sink. Such a heat transfer may employ a heat pipe. A thermoelectric cooler (TEC) may be provided between the thermally conductive member and the heat sink to allow for temperature control of the Faraday optic. This approach enables a convenient control of the actual rotation angle delivered by the Faraday optic and may be used to optimize optical isolation. Temperature control of the Faraday optic to a given set point may be automated by a closed loop circuit involving temperature sensing and TEC current control.

The polarization optics splits the unpolarized input beam from an optical fiber into “ordinary” beam (with p-polarization) and “extraordinary” beam (with s-polarization). The polarization planes of the two beams are be perpendicular to each other and the optical axes of the beams are physically separated. The subject OI can practiced with a number of known approaches to beam “splitting” including the use of birefringent materials and thin film polarizers. The polarization optics may further comprise a half-wave plate to rotate polarization planes of the ordinary and extraordinary beams by 45 degrees. Additional polarizers may be added into the paths of the ordinary and extraordinary beams to further improve optical isolation.

The input optics assembly comprises a fiber connector for attaching and positioning the input optical fiber, optics for collimating the optical beam from the fiber, and a beam expanding telescope to convert the collimated beam with a circular footprint to a collimated beam with an elliptical footprint of a large area. Beam expansion is preferably practiced in the direction perpendicular to the direction in which the unpolarized beam is split into the ordinary and extraordinary beams. Enlarging the beam footprint beneficially reduces intensity of the beam, which reduces the likelihood of optical damage in the OI. The elliptical ordinary and extraordinary beams are incident onto the Faraday optic with their footprints adjacent to each other.

In addition, the larger beam footprint also beneficially reduces the likelihood and/or intensity of hot spots in the Faraday optics. The output optics assembly comprises a fiber connector for attaching and positioning the input optical fiber, optics for focusing the optical beam into the fiber, and a beam compacting telescope to convert the beam with an elliptical footprint to a collimated beam with a circular footprint for injection into the fiber.

In some embodiments of the invention, two FRs are used in tandem to further improve optical isolation.

It is the object of the invention to provide an OI for laser beams at near 2 μm wavelength.

It is another object of the invention to provide an OI for laser beams at high-average power.

It is yet another object of the invention to provide an OI for laser beams with high pulse energies.

It is a further object of the invention to provide an OI with active cooling.

It is yet further object of the invention to provide an OI with wavelength tuning.

It is still further object of the invention to provide an OI for unpolarized laser beams.

These and other objects of the present invention will become apparent upon a reading of the following specification and claims.

### BRIEF DESCRIPTION OF THE DRAWINGS

FIG. 1 is a schematic diagram of prior art OI for unpolarized laser beams showing the path of forward propagating radiation.

FIG. 2 is a schematic diagram of prior art OI for unpolarized laser beams showing the path of backward propagating radiation.

FIG. 3 is a schematic diagram of the innovative OI in accordance with one embodiment of the invention used for unpolarized laser beams and showing the path of forward propagating radiation.

FIG. 4 is a detailed schematic diagram of a Faraday rotator for the OI shown in FIG. 3.

FIG. 5A is a schematic diagram of a polarizing separator using birefringent optics.

FIG. 5B is a schematic diagram of an alternative polarizing separator using birefringent optics.

FIG. 5C is a schematic diagram of a polarizing separator using thin film polarizers.

FIG. 5D is a schematic diagram of an alternative polarizing separator using thin film polarizers.

FIG. 6 is a schematic diagram of the input beam optics.

FIG. 7 is a schematic diagram of the output beam optics.

FIG. 8 is a diagram of the expanded laser beam footprints on the Faraday optics.

FIG. 9A is a schematic diagram of a telescope using cylindrical lenses.

FIG. 9B is a schematic diagram of a telescope using anamorphic lenses.

FIG. 9C is a schematic diagram of a combination collimator and telescope using cylindrical lenses.

FIG. 10 is a schematic diagram of a portion of the innovative OI of FIG. 3 showing the path of backward propagating radiation.

FIG. 11 is a schematic diagram of another embodiment of the inventive OI using polarizing separators with thin film polarizers and forward beam path.

FIG. 12A is a schematic diagram of the inventive OI of FIG. 11 showing the path of backward propagating radiation.

FIG. 12B is a schematic diagram of the inventive OI of FIG. 11 with beam path polarizers removed and showing the path of backward propagating radiation.

FIG. 13 is a schematic diagram of alternative construction of beam path polarizers.

FIG. 14 is a schematic diagram of a modified embodiment of the inventive OI of FIG. 11 with repositioned alignment prisms.

FIG. 15 is a schematic diagram of yet another embodiment of the inventive OI using polarizing separators with thin film polarizers, two Faraday optics, and showing a forward beam path.

FIG. 16 is a schematic diagram of the inventive OI of FIG. 15 showing the path of backward propagating radiation.

FIG. 17 is a cross-sectional view of an alternative Faraday rotator.

FIG. 18 is view of a prospective opto-mechanical layout of the inventive OI of FIG. 11 with the Faraday rotators of FIG. 17.

FIG. 19 is a view of optical isolator assembly representing one preferred opto-mechanical configuration of the inventive optical isolator 50 of FIG. 15 with the Faraday rotator of FIG. 17.

FIG. 20 is a cross-sectional view of an alternative Faraday rotator, which is a variant of the Faraday rotator 150′ of FIG. 17.

FIG. 21 is an isometric view of the thermally conductive member with a hole for heat pipe insertion.

FIG. 22 is an isometric view of the permanent magnet ring equipped with a clearance groove for heat pipe insertion.

FIG. 23 shows a cross-sectional view of another alternative Faraday rotator, which is a variant of the Faraday rotator of FIG. 20.

FIG. 24 is an isometric view of the base pole piece equipped with clearance grooves.

FIG. 25 is an isometric view of an alternative arrangement of the Faraday optic on the thermally conductive member.

FIG. 26 is a schematic diagram of the temperature control loop for Faraday optics.

FIG. 27 is a schematic diagram showing the control loop of FIG. 26 operated by electricity generated by a photovoltaic cell using a small portion of the incident laser light.

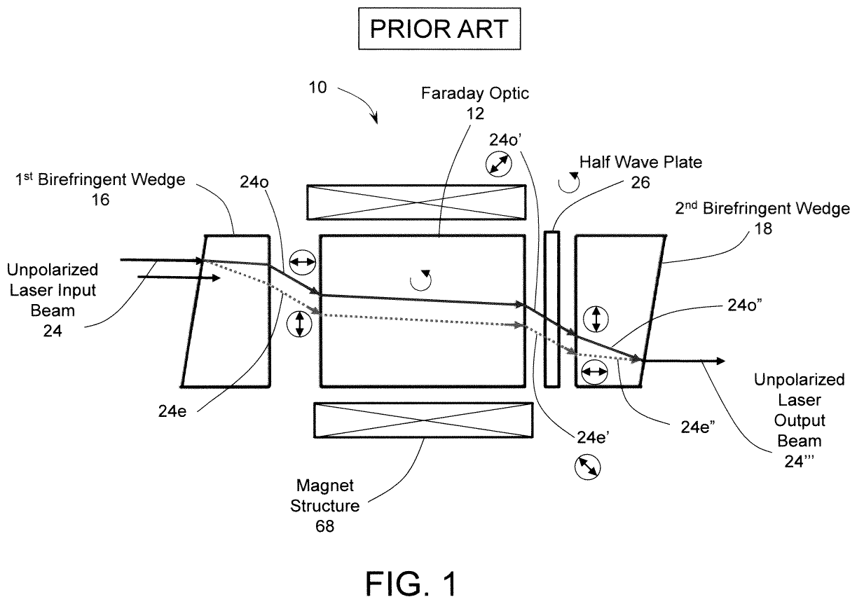

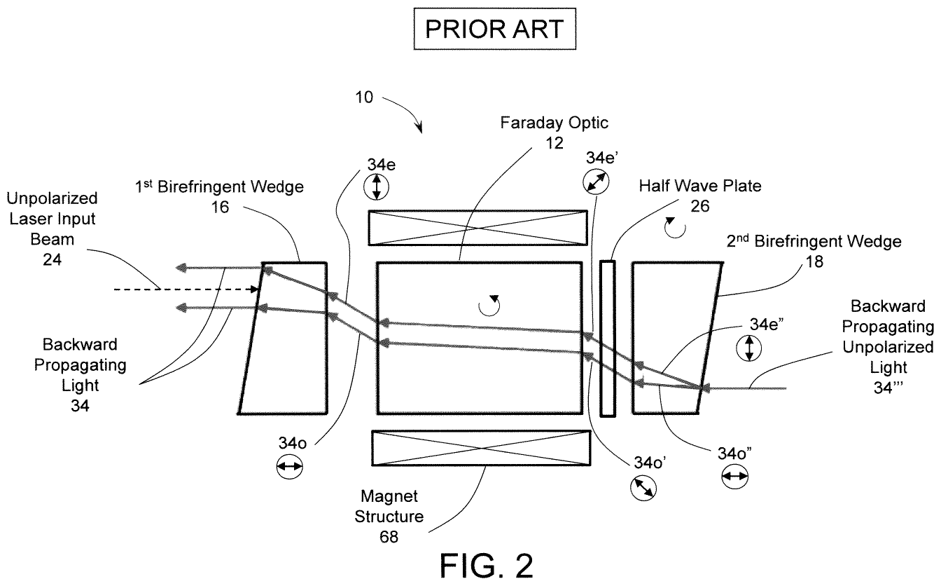

### DETAILED DESCRIPTION OF THE PREFERRED EMBODIMENTS

Selected embodiments of the present invention will now be explained with reference to drawings. In the drawings, identical components are provided with identical reference symbols in one or more of the figures. It will be apparent to those skilled in the art from this disclosure that the following descriptions of the embodiments of the present invention are merely exemplary in nature and are in no way intended to limit the invention, its application, or uses.

Certain terminology is used herein for convenience only and is not to be taken as a limitation on the invention. For example, words such as “upper,” “lower,” “left,” “right,” “horizontal,” “vertical,” “upward,” and “downward” merely describe the configuration shown in the FIGS. Indeed, the components may be oriented in any direction and the terminology, therefore, should be understood as encompassing such variations unless specified otherwise.

In the drawings, like reference numerals designate corresponding or similar elements throughout the several views.

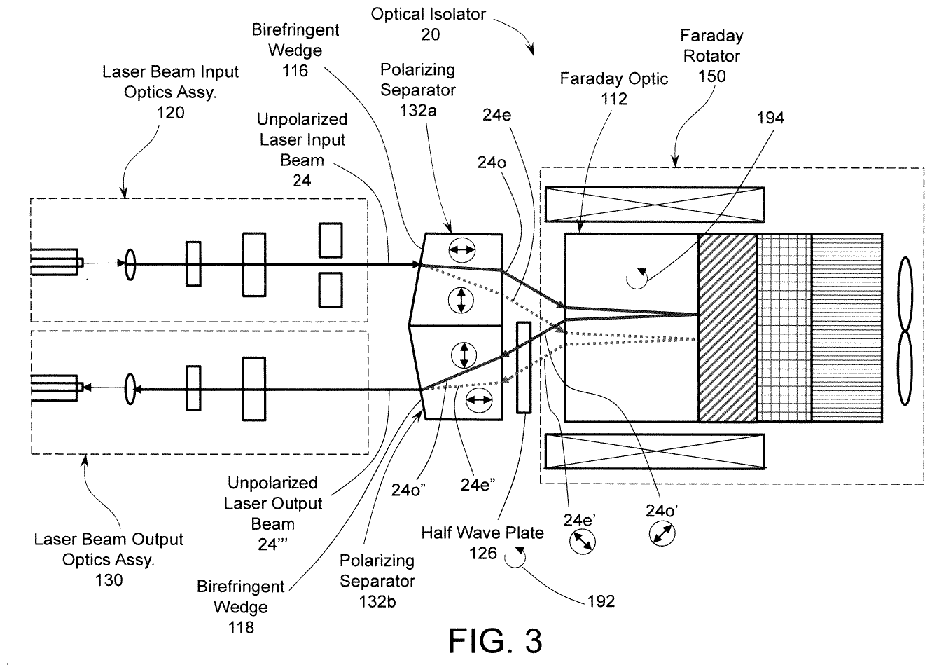

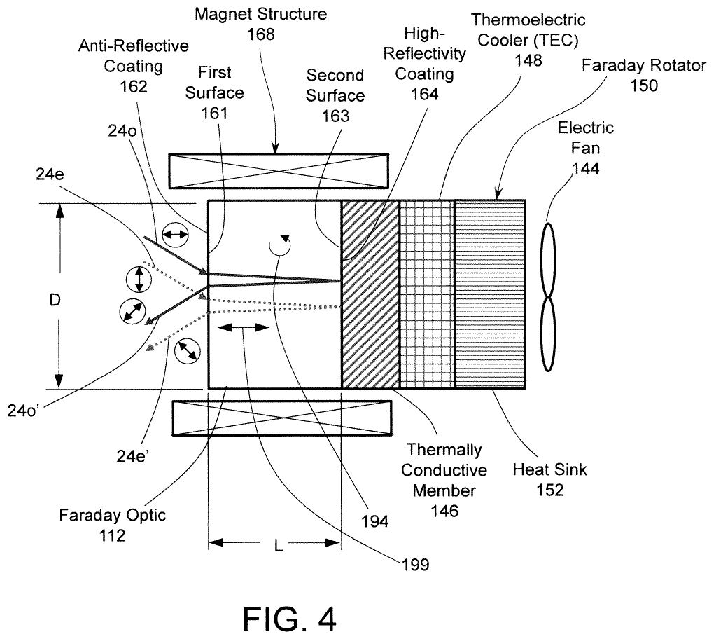

Referring now to the drawings, an OI 20 in accordance with one preferred embodiment of the subject invention is shown in FIG. 3. The OI 20 generally comprises a Faraday rotator 150, polarizing separators 132a and 132b, half-wave plate 126, beam input assembly 120, and beam output assembly 130. The Faraday rotator 150 is shown in more detail in FIG. 4 and it further comprises a Faraday optic 112, magnet structure 168, and a thermally conductive member 146. In some embodiments of the subjection invention, the Faraday rotator 150 may further comprise a thermoelectric cooler (TEC) 148 and/or an electric fan 144. The Faraday optic 112 is made of a suitable magneto-optic material exhibiting a strong magneto-optic effects (i.e., high Verdet constant) that also has a high transmission at the wavelength of incident laser beam. The Faraday optic 112 material may be provided in a crystal or ceramic (polycrystalline) form. For operation with near 2 μm laser light, examples of suitable magneto-optic material include but are not limited to yttrium iron garnet (YIG), bismuth-substituted yttrium iron garnet (Bi:YIG), bismuth iron garnet (BIG), cerium-doped yttrium iron garnet (Ce:YIG), cerium iron garnet (CIG), dysprosium sesquioxide (Dy₂O₃), or terbium sesquioxide (Tb₂O₃). In some aspects of the invention, the Faraday optic 112 may be formed as a relatively thin film deposited on a substrate. Referring now again to FIG. 4, the Faraday optic 112 is generally formed as a flat member having a lateral dimension “D” and a thickness “L” comprising a first surface 161, a second surface 163, an antireflective (AR) coating 162, and a high-reflectivity (HR) coating 164. The first surface 161 is adapted to receiving and transmitting an optical beam. In particular, the first surface 161 is made optically flat and it is equipped with the AR coating 162. The AR coating 162 should have a very low reflectivity (preferably less than 0.5%) at the light wavelength (or wavelength band) near 2 μm. The second surface 163 is generally parallel to the first surface 161 and it is adapted to receiving and reflecting an optical beam. In particular, the second surface 163 is made optically flat and it is equipped with the HR coating 164. The HR coating 164 preferably has very high reflectivity (preferably higher than 99.5%) at the light wavelength (or wavelength band) near 2 μm. The HR coating 164 may be further over-coated on the exterior side (facing the thermally conductive member) with a metal coating or coatings (not shown) to allow for soldering to the thermally conductive member 146.

The magnet structure 168 comprises a rare-earth permanent magnet and it may also include components made of soft magnetic material such as iron or low-carbon steel. The permanent magnet is preferably a rare-earth permanent magnet such as samarium cobalt (SmCo) or neodymium boron iron (NdBFe). In one aspect of the invention, the magnet structure 164 is generally formed as hollow cylinder magnetized in the direction of its axis of symmetry as indicated by the double arrow 199. The Faraday optic 112 is immersed in magnetic field generated by the magnet structure. Preferably, the magnet structure 168 and the Faraday optic 112 are arranged so that the polarization plane of incident optical beam is rotated by 22.5 degrees upon a single pass through the Faraday optic 112. This translates to a rotation of 45 degrees upon a round trip through the Faraday optic 112. The round trip is defined as a continuous optical path from the AR coating 162 to the HR coating 164 followed by a refection from the HR coating and a travel to the AR coating 162. Such an optical path may have a “V” shape as, for example, indicated in FIG. 4. In one embodiment of the subject invention, Faraday optic 112 is placed inside the magnet structure 168, which is formed as a hollow cylinder. In another embodiment of the invention, the Faraday optics 112 is placed onto a magnetic pole of the magnet structure. Certain materials suitable for forming the Faraday optic 112 such as YIG, Bi:YIG, Ce:YIG, and BIG, may be magnetically saturated at modest magnetic excitation fields. It is well known that for YIG, the saturation magnetization is reached at the excitation field of about 1000 Oersted. Preferably, the magnet structure 168 and the Faraday optic 112 are arranged so that the Faraday optic 112 is magnetically saturated.

The second surface 163 of the Faraday optic 112 is mechanically attached and thermally coupled to the thermally conductive member 146. Suitable attachment may be provided by adhesive bonding (e.g., by using epoxy) and by a metallurgical bonding (e.g., by soldering). This arrangement allows for the waste heat generated by the laser beam within the Faraday optic 112 to be conducted to the second surface 163 in a direction generally parallel to the optical axis of the laser beam and transferred into the thermally conductive member 146. When the Faraday optic 112 is soldered to the thermally conductive member 146, the thermally conductive member is preferably made of material having a coefficient of thermal expansion (CTE) matched to that of the Faraday optic. In one embodiment of the subject invention, the thermally conductive member 146 is directly thermally coupled to the heat sink 152, which may be cooled by ambient air or by a liquid coolant. In yet another embodiment of the subject invention, the thermally conductive member 146 is made (at least in part) of soft magnetic material. This approach beneficially reduces the reluctance of the magnetic circuit and homogenizes the magnetic field near the Faraday optics 112. If the heat sink 152 is cooled by ambient air, an electric fan 144 may be provided to increase the air flow over the heat sink, thus improving the removal of heat. In another embodiment of the subject invention shown in FIG. 4, the thermally conductive member 146 is thermally coupled to a cold side of TEC 146 while the hot side of the TEC is thermally coupled to the heat sink 152. In this embodiment, TEC 146 may be operated to pump the waste heat from the Faraday optics 112 to a heat sink 152, which may be at a substantially higher temperature. This approach beneficially offers the Faraday optics 112 to operate at temperatures well below the ambient temperature. Other benefits include temperature “tuning” of the Faraday optics 112 to optimize the isolation. For example, the temperature dependence of the Verdet constant of YIG is about 0.042 degrees of rotation per degree C. of temperature change. In addition, the wavelength dependence of the Verdet constant of YIG on temperature is about 1 nanometer per degree C. of temperature change. Therefore, the TEC 146 offers a convenient way to tune the optimum wavelength of the Faraday optic 112.

FIG. 3 shows the polarizing separator 132a comprising a birefringent wedge 116, polarizing separator 132b comprising a birefringent wedge 118, and half-wave plate 126.

The first birefringent wedge 116 is arranged to split an incident unpolarized beam 24 into ordinary beam 24o and extraordinary beam 24e and direct them into the Faraday rotator 150. The encircled arrow symbols in the figure indicate the polarization state of an adjacent beam at that location. The Faraday rotator 150 rotates the respective polarization planes of beams 24oand 24e by 45 degrees in counterclockwise direction and sends them as beams 24o′ and 24e′. onto the half-wave plate. The half-wave plate 126 is adapted to receiving the beams 24o′ and 24e′ and rotating them by additional 45 degrees in the same direction as the Faraday rotator 150, thus respectively forming beams 24o″ and 24e″. For this purpose, the optical axis of the half-wave plate 126 is rotated by an angle of 22.5 degrees with respect to the original extra-ordinary linear polarization (beam 24e). The halfwave plate 126 may be made of quartz. The birefringent wedge 118 is arranged receive the beams 24o″ and 24e″, and combine them into a single unpolarized output beam 24′″. The birefringent wedges 116 and 118 are preferably fabricated from the same material (e.g., quartz), with the same dimensions and cut at the same angle. In some embodiments of the subject invention the birefringent wedges 116 and 118 may be cojoined to form a single component. Suitable birefringent materials for construction of birefringent wedges 116 and 118 include but are not limited to: YVO₄, TiO₂, CaCO₃, LiNbO₃, MgF₂, SiO₂ (quartz), and PbMoO₄.

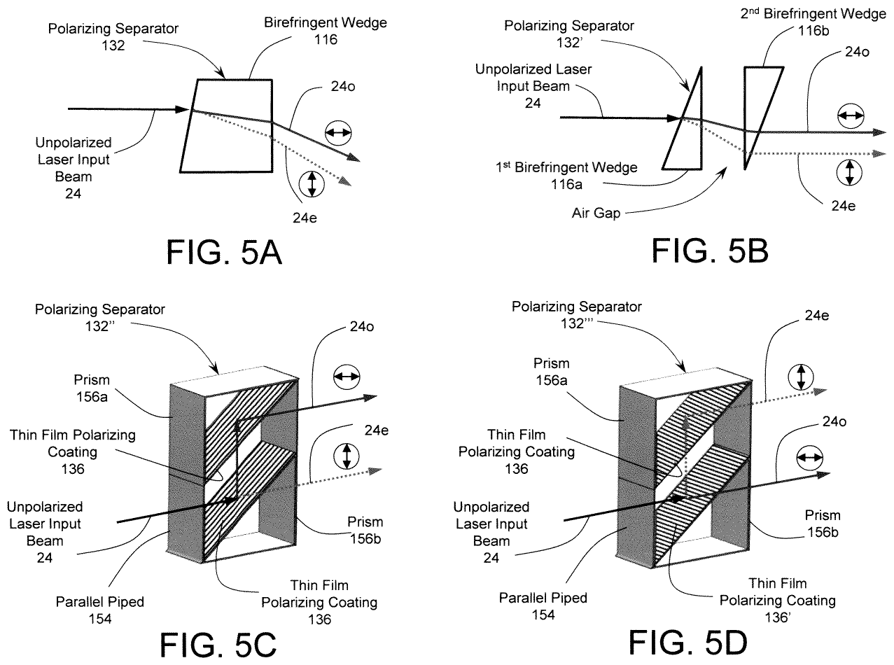

The purpose of the polarizing separator 132 (see, e.g., FIG. 5A) is to split an unpolarized beam into two polarized beams with mutually perpendicular polarization planes and separate the two beams in space. The inventive OI may also use alternative polarizating approaches. For example, the birefringent wedge 116 may be replaced by two separate birefringent wedge prisms 116a and 116b separated by an air gap as shown in FIG. 5B. This arrangement is advantageous for beams with large transverse dimension (parallel to the face of the drawing), which would require a correspondingly large monolithic birefringent wedge 116. Such a monolithic component may be challenging to fabricate. Furthermore, a long beam path through a large monolithic wedge is conducive to significant absorption of the laser light, which, in high-average power operating regime may drive deleterious thermo-optical distortions. In contrast, the design with two separate and smaller birefringent wedge prisms reduces that possibility. The birefringent wedge 118 may be similarly replaced.

Another approach to splitting an unpolarized beam into two polarized beams with mutually perpendicular polarization planes and separating the beams in space is to use thin film polarizers. One implementation of this approach is a polarizing separator 132″ shown in FIG. 5C, which uses two right angle prisms 156a and 156b, a parallelepiped 154, and polarizing coating 136. The prisms 156a and 156b preferably have a cross-section that is an isosceles triangle. The prisms and the parallelepiped are preferably made from UV-grade fused silica with low OH content to reduce the susceptibility for absorbing light at near the 2 micron wavelength. The polarization coating 136 is applied to the hypotenuse of each prism 156 in a way so as to reflect the ordinary (p-polarized) beam 24o and to pass the extraordinary (s-polarized) beam 24e created from the incident unpolarized beam 24. The parallel-piped 154 is placed between the two prims and preferably bonded thereto using an index-matched optical adhesive or an adhesive free bond such as optical contacting or optical contacting followed by a heat treatment. The resulting polarizing separator 132″ can be used to replace the birefringent wedge 116 and/or 118. A path of forward propagating light is shown as a solid heavy line. The path of backward propagating light with indicated polarizations is indicated as a dotted heavy line. FIG. 5D shows a polarizing separator 132′″, which is a variant of the polarizing separator 132″ of FIG. 5C with the polarization direction of the coatings 136′ being rotated 90 degrees. In particular, the polarization coating 136′ is applied to the hypotenuse of prisms 156a and 156bin a way so as to reflect the extraordinary (s-polarized) beam 24o and to pass the extraordinary (p-polarized) beam 24e created from the incident unpolarized beam 24.

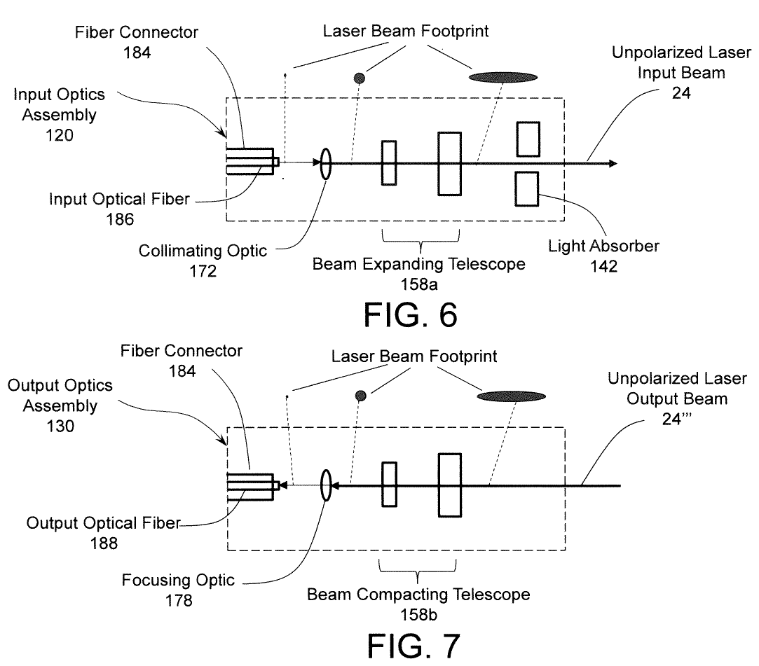

FIG. 6 shows the input optics assembly 120 comprising a fiber connector 184, collimating optics 172, and a light absorber 142. The fiber connector 184 provides a means for attaching and positioning the input optical fiber 186. The collimating optics 172 receives unpolarized light from the end of the optical fiber 186 and collimates it to form an unpolarized input beam 24 for injection into the polarizing separator downstream. The light absorber 142 is placed in vicinity of the beam 24 and arranged to intercept the backward propagating radiation as will be described below. In some embodiments of the invention, the input beam assembly 120 may further include a beam expanding telescope 158a to convert the collimated beam with a circular footprint to a collimated beam with an elliptical footprint. Enlarging the beam footprint beneficially reduces the beam intensity, which reduces the likelihood of optical damage. In addition, the larger beam footprint also beneficially reduces the likelihood and/or intensity of hot spots in the Faraday optics.

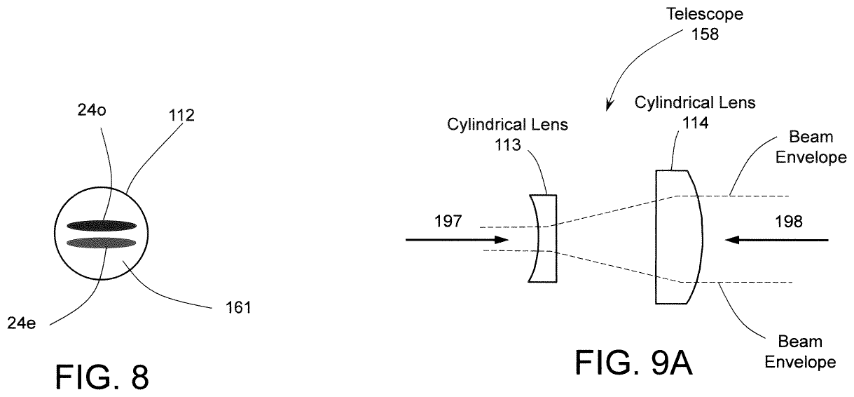

FIG. 7 shows the output optics assembly 130 comprising a fiber connector 184 and focusing optics 178. The fiber connector 184 provides a means for attaching and positioning the output optical fiber 188. The focusing optics 178 receives unpolarized output beam 24′″ from the upstream polarizing combiner and focuses it onto the end of the output fiber 188. If the input optics assembly 120 includes the cylindrical optics telescope 158 to produce a collimated beam with an elliptical footprint, then the output optics assembly 130 further includes a corresponding cylindrical optics telescope 158b to compress the elliptical footprint of beam 24′″ to a collimated beam with a circular footprint prior to sending it to the focusing optics 178 and injecting it into the output fiber 188. FIG. 8 shows exemplary elliptical footprints of the ordinary beam 24o and extra-ordinary beam 24e and their relative positions on the first surface 161 of Faraday optic 112 (FIG. 4).

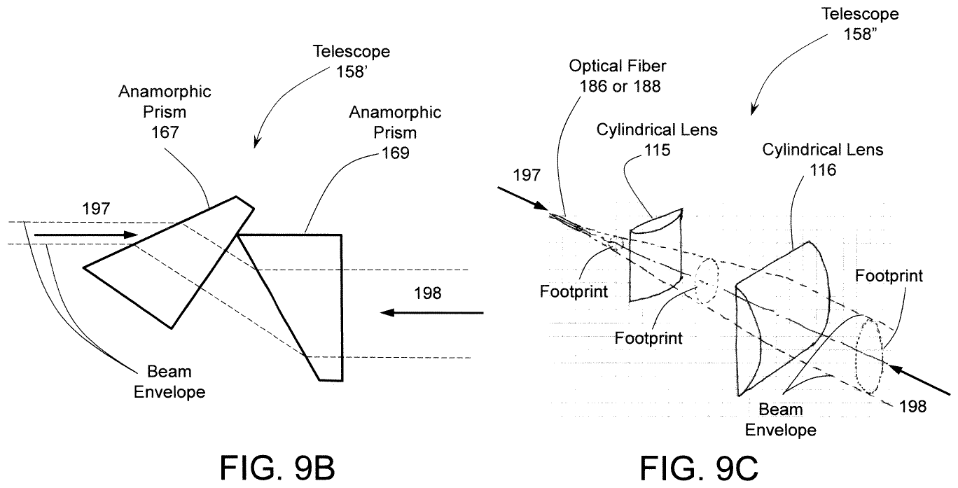

The telescope 158 may be formed as cylindrical lenses 113 and 114 arranged as indicated in FIG. 9A. When a laser beam propagates through the telescope 158 in direction indicated by an arrow 197, its footprint is expanded in the indicated transverse direction. For example, a beam with a circular footprint is expanded to an elliptical footprint. When a laser beam propagates through the telescope 158 in direction indicated by an arrow 198, its footprint is compacted. For example, a beam with an elliptical footprint is compacted to a circular footprint. Similar end result may be achieved with a telescope 158′ formed as a pair of anamorphic prisms 167 and 169 shown in FIG. 9B. Yet another approach shown in FIG. 9C combines the function of a beam collimation and expansion. Beam from the optical fiber 186 is naturally circular and diverging (expanding). A pair of positive cylindrical lenses 115 and 116 may be used to separately collimate in the two principal transverse directions a circular beam propagating in the direction of arrow 197 and produce a beam with elliptical footprint. Conversely, an elliptical beam propagating in the direction of arrow 198 is compacted and converted to a circular footprint.

In operation of the OI 20 of FIG. 3, the input optical fiber 186 (FIG. 6) is installed in the fiber connector 184 of the input optics assembly 120. The output optical fiber 188 (FIG. 7) is installed in the fiber connector 184 of the output optics assembly 130. Laser light is directed from the end of the input optical fiber 186 into the collimating optics 172, is collimated by it, expanded by the telescope 158 (FIG. 6) in the direction normal to the face of the drawing, and directed as the unpolarized laser input beam 24 into the polarization separator 132a (FIG. 3). The polarizing separator 132a splits the beam 24 into two beams: “ordinary” beam 24o (with p-polarization) and “extraordinary” beam 24e (with s-polarization). The encircled arrow symbols in the figure indicate the polarization state of an adjacent beam at that location. The two beams 24o and 24e are directed the to the Faraday optic 112, enter the optic through the AR coating 162 (FIG. 4) into the first surface 161, pass through the bulk of the optic 112, are reflected by the HR coating 164, pass through the bulk of the optic again in generally opposite direction, and exit the optic through the AR coating 162. The Faraday optic 112 is immersed in the magnetic field produced by the magnet structure 168. The two passes (forward and back) through the Faraday optic 112 cause the polarization planes of both beams 24o and 24e to be rotated by 45 degrees in the direction indicated by the arrow 194, thus producing beams 24o′ and 24e′. Upon subsequent passage of beams 24o′ and 24e′ through the half wave plate 126, their polarization planes are rotated by additional 45 degrees in the direction indicated by the arrow 192 (same direction as in the Faraday optic) thus producing beams 24o″ and 24e″. More specifically, the polarization planes of beams 24o″ and 24e″ are respectively rotated by a total of 90 degrees compared to the original beams 24o and 24e. The beams 24a″ and 24b″ are directed through the polarizing separator 132b where they are recombined and transferred as an unpolarized beam 24′″ to the telescope 158 in the laser beam output optics 130 (FIG. 6). The telescope 158b converts the beam footprint from elliptical to circular and transfers it to the focusing optics 178 that injects the beam into the output optical fiber 188. Note that the half-wave plate 126 may be placed in the beam path anywhere between the polarizing separator 132a and 132b.

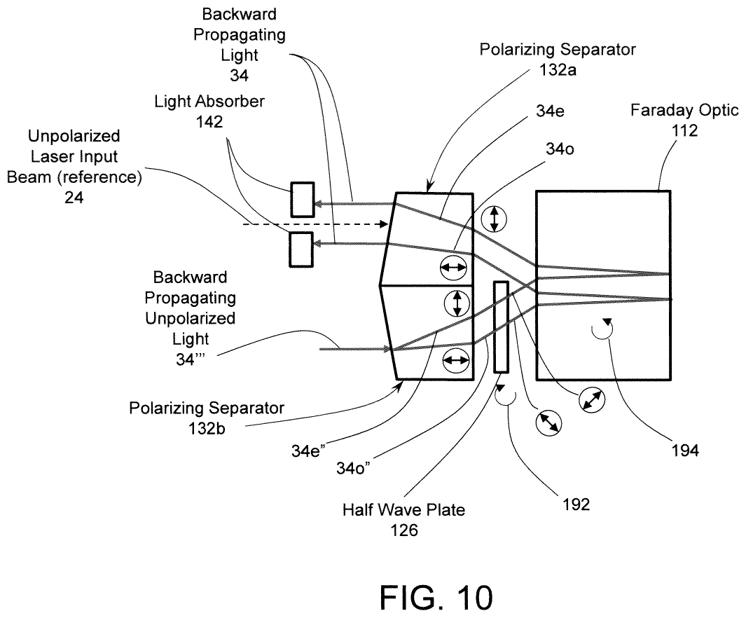

FIG. 10 shows the path of light 34 traveling in the backward direction through the polarizing separator 132b and the Faraday optic 112. The backward travelling light 34′″ (generally unpolarized) enters the birefringent wedge 118 where it is separated into a beam 34o″ having an ordinary polarization and a beam 34e″ having an extraordinary polarization. Next, the polarization planes of beams 34o″ and 34e″ are rotated 45 degrees by the half-wave plate 126 in the direction indicated by arrow 192. The resulting beams 34o′ and 34e′ are then rotated by the Faraday optic 112 by 45 degrees in the direction indicated by arrow 194, which is opposite to the direction of rotation acquired in the half-wave plate 126. Thus, the respective polarization directions of resulting beams 34o and 34e are same as for the beams 34o″ and 34e″. The reason is that the half-wave plate rotates the polarization plane relative to the direction of propagation, while the FR rotates the polarization plane relative to the direction of magnetization. Consequently, the beams 34o and 34e cannot be recombined into one in the birefringent wedge 116 and continue on as separate beams that are intercepted and neutralized by the light absorbers 142 installed in the input optics assembly 120 (FIG. 6). Note, that the at this point the backward propagating light is not collinear with the laser input beam 24 but rather offset from it. In some embodiments of the invention, the light absorbers 142 may be replaced by reflective surfaces that redirect the path of the beams 34o and 34e to the exterior of the OI 20.

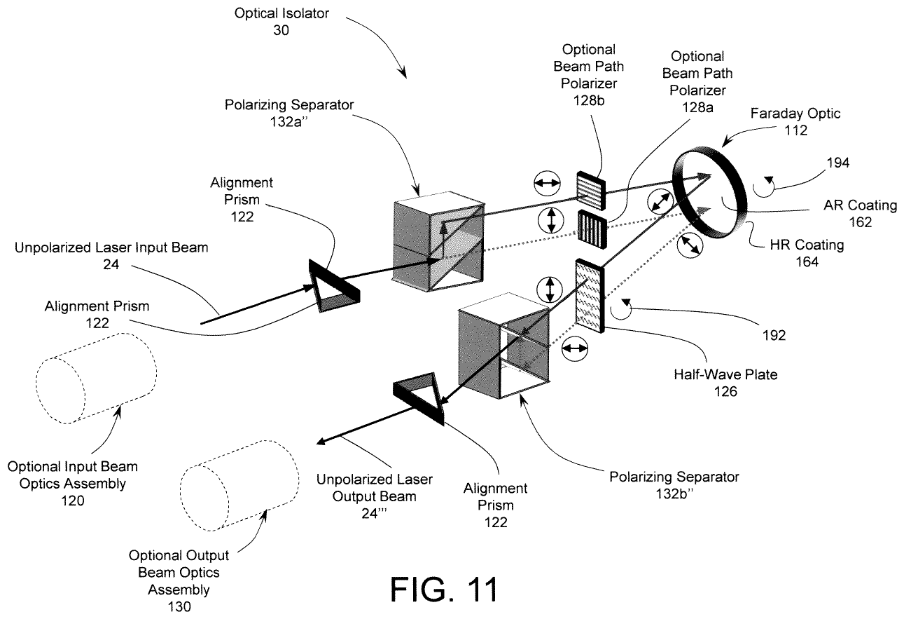

Referring now to FIG. 11, there is shown an OI 30 in accordance with another embodiment of the invention. The OI 30 uses two polarizing separators 132a″ and 132b″ and half-wave plate 126. The polarizing separator 132b″ is same as the polarizing separator 132a″ but it is rotated about 180 degrees from the polarizing separator 132a″. The OI 30 may also include beam path polarizers 128a and 128b, which may be placed between the polarizing separator 132a″ and the Faraday optics 112. The beam path polarizers 128a and 128b are preferably formed as thin film polarizers. Polarization direction of the polarizers 128a and 128b is indicated by the stripes. The beam path polarizers 128a and 128b are preferably placed at slight angle with respect to the optical axis so that the backward propagating light with mismatched polarization would be reflected off-axis (sideways) onto an absorber. The OI 30 may also include one or more alignment prisms 122 to align the polarizing separators 132a″ and 132b″ to mutually parallel input beam 24 and output beam 24′″. In operation, an unpolarized input beam 24 is split in the polarizing separator 132a″ into an extraordinary beam, which propagates straight to the Faraday optics 112 and an ordinary beam, which is reflected upward by the coating 136 (FIG. 5C). This beam is then reflected again by the second coating 136 toward the Faraday optics 112. This arrangement creates a predetermined offset between the parallel ordinary and extraordinary beams. After a 45 degree polarization plane rotation by the Faraday optics 112, the polarization planes of each of the ordinary and extraordinary beams experience additional 45 degree rotation by the half-wave plate 126. The ordinary beam, which is now rotated full 90 degrees from its original state is incident on the polarization separator 132b″ and passes through the coating 136b. The extraordinary beam now having its polarization rotated full 90 degrees from its original state is incident on the polarization separator 132b″, is reflected by two coatings 136 (FIG. 5C), and adjoins the ordinary beam to form the unpolarized output beam 24′″.

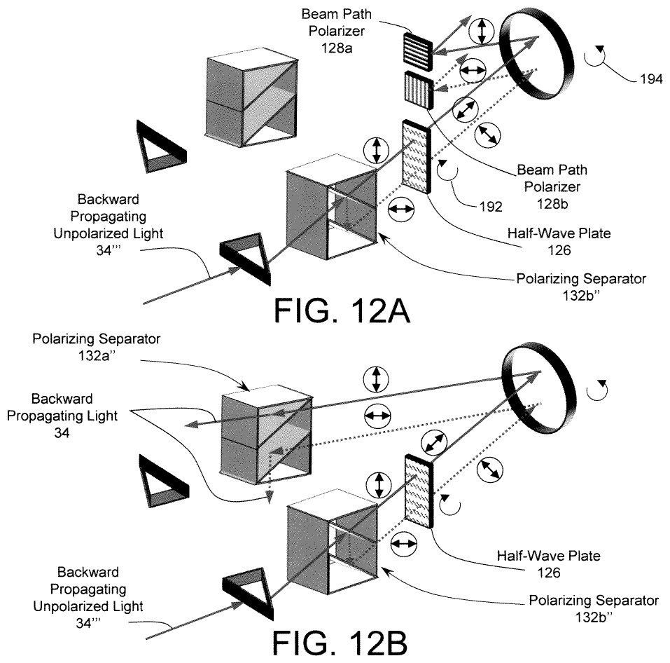

FIG. 12A shows the path of backward propagating light 34′″ through the OI 30. The backward travelling light enters the polarizing separator 132b″ and it is split into extraordinary and ordinary beams. For each the extraordinary and ordinary beam, the subsequent rotation of the polarization plane by the halfwave plate 126 and the Faraday optics 112 essentially cancel out. As a result, the polarization planes of the extraordinary and ordinary beam are now perpendicular to the polarization of their respective beam path polarizers 128aand 128b, and the consequently reflected by them to the side. FIG. 12B traces the path of backward travelling light 34′″ through the through the OI 30 that does not use the beam path polarizers 128. The figure shows that the backward travelling light is released through the polarization separator 132a″ as separate ordinary and extraordinary beams that are is not collinear with the input beam and, therefore, can be intercepted and neutralized.

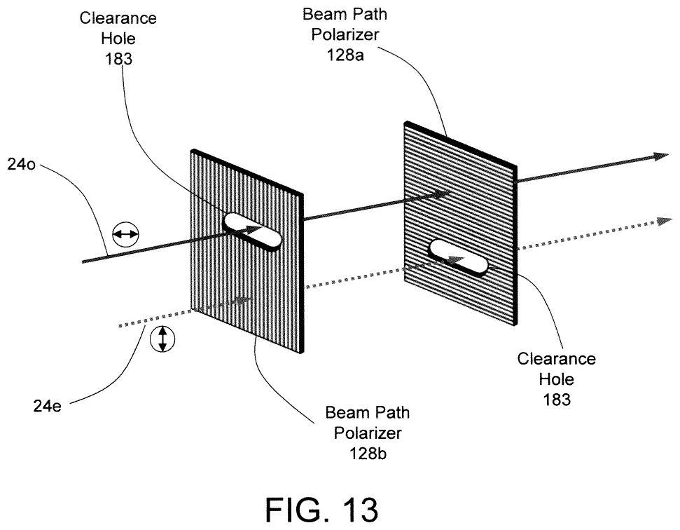

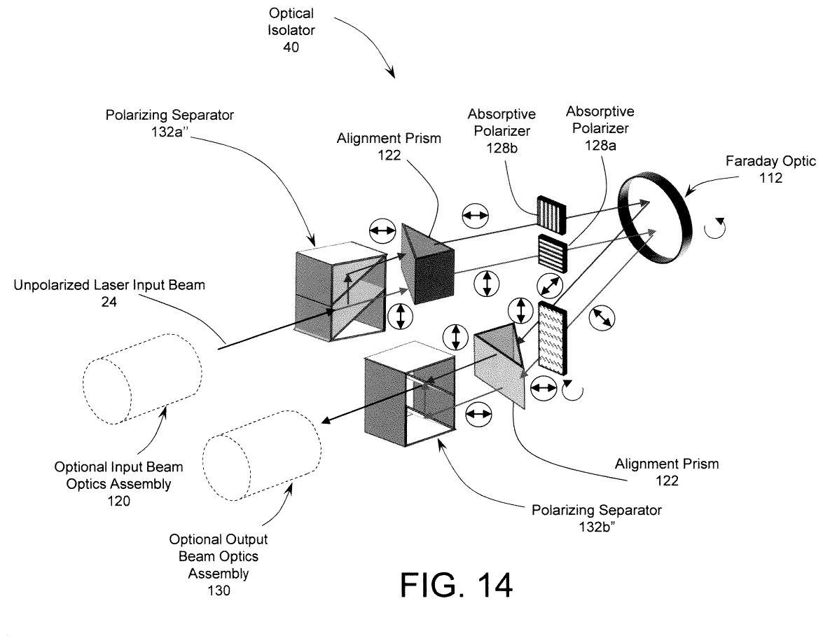

Adding the beam path polarizers 128a and 128b is known to improve optical isolation. Beams passing through the polarizers 128a and 128b may be relatively closely spaced (typically 1 to few millimeters apart). The challenges with precisely positioning small polarizers 128a and 128b may be overcome with polarizers 128a′ and 128b′ are that larger and have an overall shaped clearance hole 183 as shown in FIG. 13. FIG. 14 shows an optical isolator 40, which is a variant of optical isolator 30 of FIG. 11. In the optical isolator 40, the alignment prism 122 are now moved over to the beam path between the polarizing separators 132″ and the Faraday optic 112.

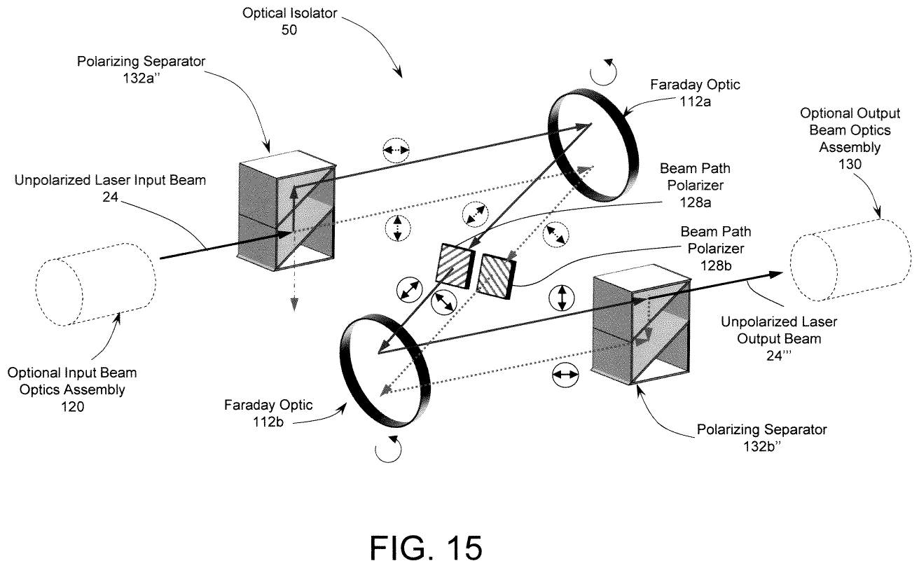

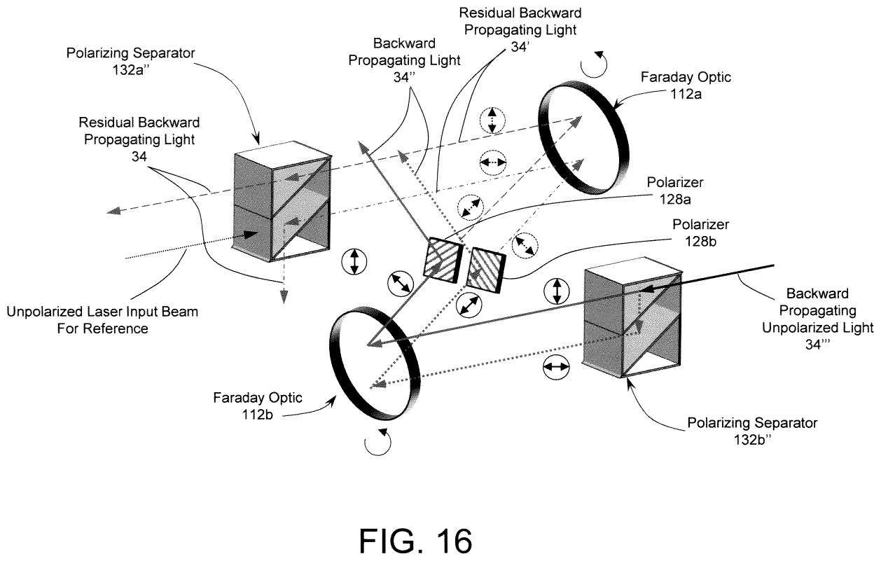

Referring now to FIG. 15, there is shown an optical isolator 50 using two Faraday optics 112a and 112b, two polarizing separators 132a″ and 132b″, and two beam path polarizers 128a and 128b. This arrangement offers higher optical isolation than the optical isolator 30 of FIG. 11. FIG. 16 shows the path of backward propagating radiation in the OI 50 of FIG. 15. In one variant of the optical isolator 50, the Faraday optics 112a and 112b can be arranged provide 22.5 degrees rotation each, thus providing a 45 degrees rotation together. This approach allows for using the Faraday optics 112a and 112b with only half the thickness “L” (FIG. 4), which improves the removal of waste heat from the optics. In particular, the resulting variant of the optical isolator 50 offers operation with about four times the average laser beam power compared to the optical isolators using the same Faraday optic material with a thickness selected for 45 degrees rotation.

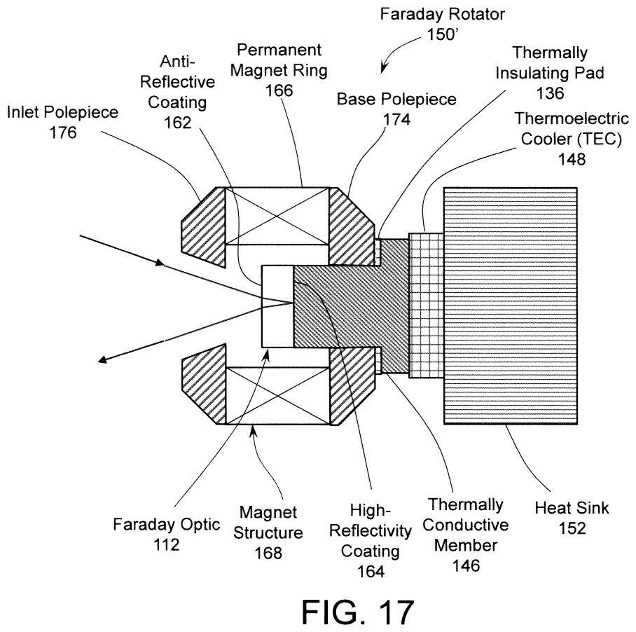

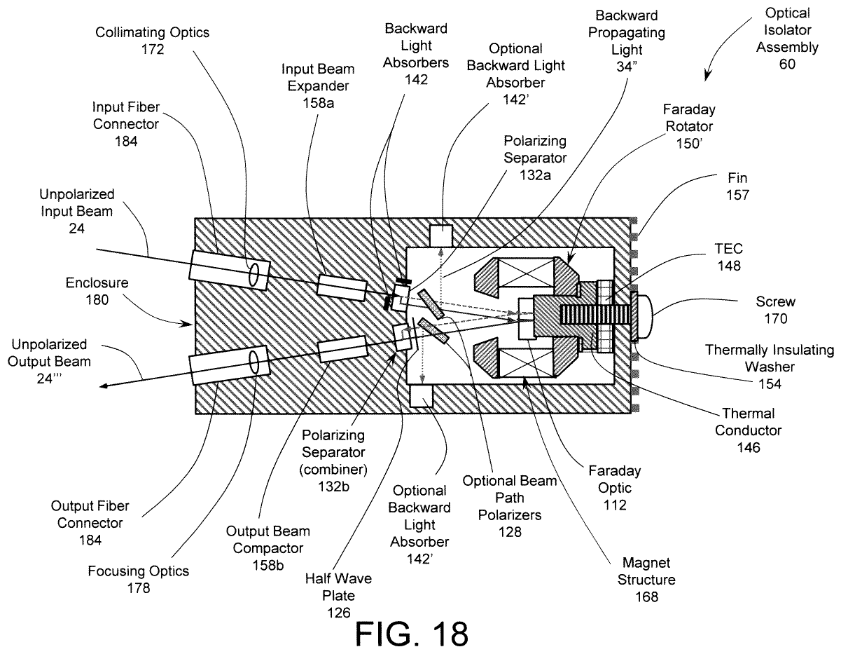

Referring now to FIG. 17, there is shown a cross-sectional view of an alternative Faraday rotator 150′, which is a variant of the Faraday rotator 150 of FIG. 4, offering compact features and high-strength magnetic field with improved uniformity. In particular, the Faraday rotator 150′ includes inlet polepiece 176 and a base polepiece 174 that are made of soft magnetic materials such as iron, low-carbon steel, Hyperco 50A, or core iron (also known as VIM VAR or Carpenter Consumet Core Iron®). Hyperco 50A and core iron are available from. Carpenter Technology in Philadelphia, PA. These polepieces reduce the reluctance of the magnetic circuit and help to make the excitation magnetic field inside the Faraday optic 112 more uniform and predictable.

Referring now to FIG. 18, there is shown an optical isolator assembly 60 representing one preferred opto-mechanical configuration of the inventive optical isolator 30 of FIG. 11. In particular, the optical isolator assembly 60 comprises a Faraday rotator 150′, polarization separator 132a, polarizing separator (combiner) 132b, half-wave plate 126, light absorbers 142 for backward propagating light, and an enclosure 180. The optical isolator 60 may further comprise an input beam and output beam optical assemblies. The input beam optical assembly may include an input fiber connector 184, collimating optics 172, and an input beam expander 158a. The output beam optical assembly may include an output fiber connector 184, focusing optics 178, and an output beam compactor 158b. Optionally, the optical isolator assembly 60 may also include beam path polarizers 128 and light absorbers 142′ for backward propagating light.

Preferably, at least a portion of the enclosure 180 is constructed from material having good thermal conductivity such as aluminum so that this portion may act as a heat sink. The Faraday rotator 150′ may be mounted with a screw 170 installed through the wall of the enclosure 180. The TEC 148 is arranged to have a clearance hole. Such TECs are commercially produced. The screw 170 preferably passes through the clearance hole in the TEC 148 and engages a thread installed in the thermally conductive member 146. In one preferred configuration, the enclosure 180 preferably has fins 157 on its eternal surface in the vicinity of the Faraday rotator 150′. A thermally insulating washer 154 is preferably installed under the head of screw 170 to reduce back-leakage of heat. Upon tightening of the screw 170, a good thermal communication is established between the TEC 148 and the fins 157. In particular, waste heat generated in the Faraday optic 112 of the Faraday rotator 150′ (FIG. 17) is conducted to the thermally conducting member 146, conveyed through the thermally conducting member 146 and transferred to the TEC 148, and conducted to the fins 157. If the optical isolator assembly 60 is used in ambient air, heat may be transferred from the fins 157 to ambient air. When the optical isolator assembly 60 is used in vacuum, heat may be transferred from the fins 157 by radiation. Alternatively, waste heat may be transferred from the enclosure 180 via thermal contact with a suitable external structure (not shown). Such an external structure may be cooled by air or by liquid.

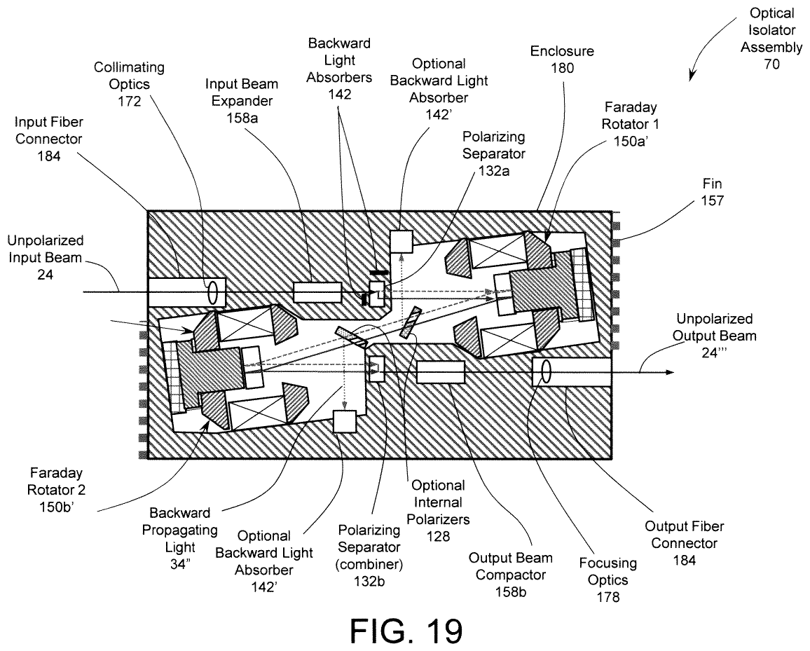

Referring now to FIG. 19, there is shown an optical isolator assembly 70 representing one preferred opto-mechanical configuration of the inventive optical isolator 50 of FIG. 15. In particular, the optical isolator assembly 70 is a variant of the optical isolator assembly 60, but it comprises two Faraday rotators, 150a′ and 150b′, rather than a single rotator 150′. As already noted above, the benefits of optical isolator with two Faraday rotators include higher optical isolation and operation higher average laser beam power compared to an optical isolator a single Faraday rotator made of the same Faraday optic material.

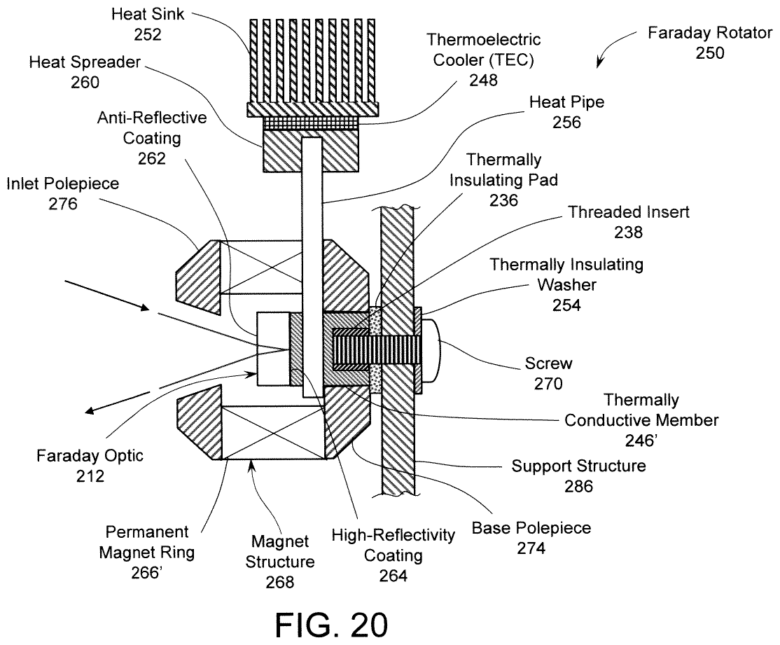

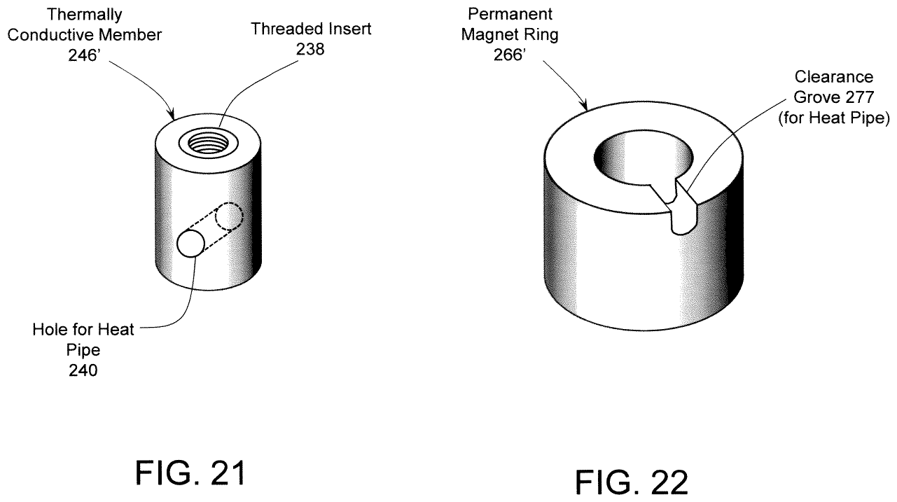

Referring now to FIG. 20, there is shown a cross-sectional view of an alternative Faraday rotator 250, which is a variant of the Faraday rotator 150′ of FIG. 17. The Faraday rotator 250 offers an alternative way of transferring waste heat to a heat sink. In particular, the Faraday rotator 250 includes a heat pipe 256, which thermally couples the thermally conductive member 246 to a TEC 248 via a heat spreader 260. One end of the heat pipe 256 is attached to the thermally conductive member 246. As shown in FIG. 21, the thermally conductive member 246 has a hole 240, which allows for insertion of the heat pipe 256. Preferably, the hole 260 provides a precision fit for the heat pipe 256 to improve thermal communication therebetween. The heat pipe 256 may be affixed to the thermally conductive member 246 by a metallurgical bond (e.g., via soldering) or adhesive bond (e.g., by high-thermal conductivity epoxy). Alternatively, the heat pipe 256 and the hole 260 may have a match-machined taper. Such an arrangement allows for a separable joint where the pipe 256 may be simply pushed in to the hole 260 and held by friction or secured with a screw.

Preferably, the thermally conductive member 246 is made of material with high thermal conductivity such as copper or its alloys (e.g., copper tungsten or copper molybdenum). Most preferably, thermally conductive member 246 is made of material having a constant thermal expansion (CTE) closely matched to the CTE of the material of the Faraday optic 212. The thermally conductive member 246 may include a threaded insert 238 to provide a more robust engagement to the threads of the screw 270 and allow for higher tightening torque. The heat pipe 256 is directed generally radially outward through the permanent magnet ring 266. For this purpose, the permanent magnet ring 266 may be equipped with a clearance groove 277 as shown in FIG. 22. Such a groove may be installed prior to magnetization of the permanent magnet ring 266. Alternatively, the groove may be installed by wire electro-discharge machining (EDM). It has been established that wire EDM machining does not significantly alter the magnetization of an already magnetized NdFeB magnets. See, e.g., “Experimental Investigation of Wire Electrical Discharge Machining of NdFeB Permanent Magnets with an RC-Type Machine” by J. Greer et al., published in Journal of Materials Engineering and Performance. March 2014.

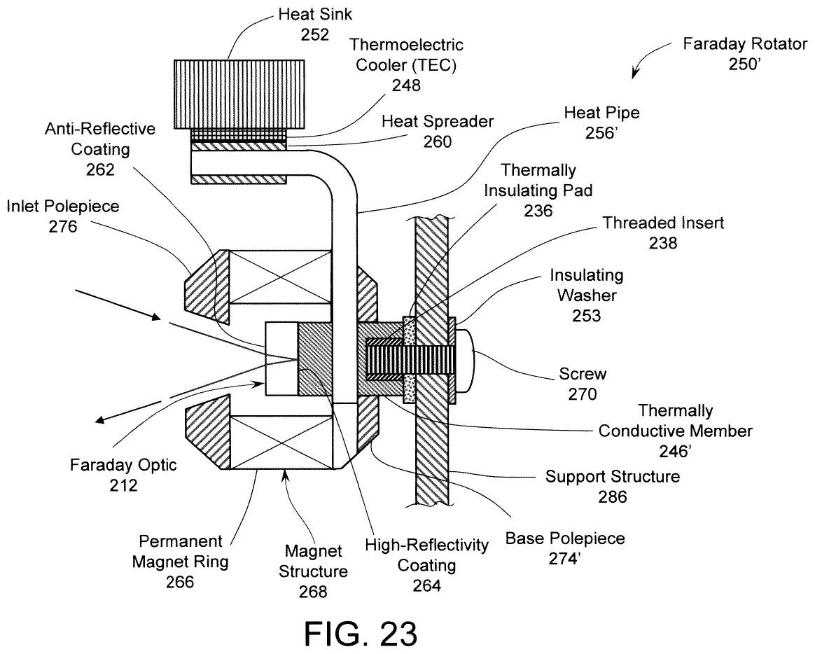

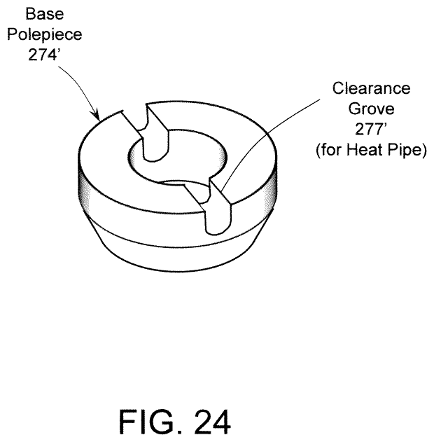

Referring now to FIG. 23, there is shown a cross-sectional view of an alternative Faraday rotator 250′, which is a variant of the Faraday rotator 250 of FIG. 19. The Faraday rotator 250′ offers a bent heat pipe 256′ that does not require grooving the permanent magnet ring 266. Instead, the heat pipe 256′ is directed through the base pole piece 274, which is equipped with one or more clearance grooves 277′ as indicated in FIG. 24.

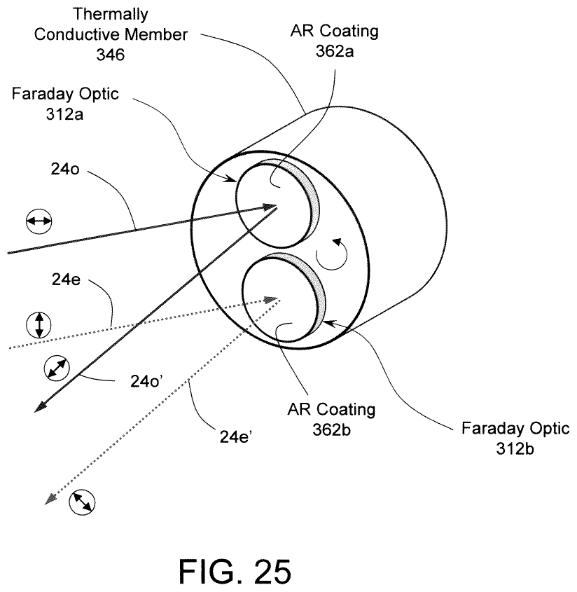

Referring now to FIG. 25, there is shown and alternative way for arranging the Faraday optic. Commonly used material for Faraday optic operating in vicinity of 2 μm wavelength is yttrium iron garnet (YIG). This material is commercially grown in boules up to about 5 to 6 mm in diameter. Such boules are then machined and sliced to disks about 5 mm in diameter. Larger YIG components have been produced in polycrystalline (ceramic) form. However, this technique is still rather experimental and not yet in commercially practice. See, e.g., “Development of optical grade polycrystalline YIG ceramics for faraday rotator” by A. Ikesue et al., in Journal of American Ceramic Society, 2018; vol. 101:pages 5120-5126. An alternative to using a single Faraday optics 112 in a Faraday rotator 150 shown in FIG. 4 is to use two Faday optics 312a and 312b arranged on a thermally conductive member 346 as indicated in FIG. 25.

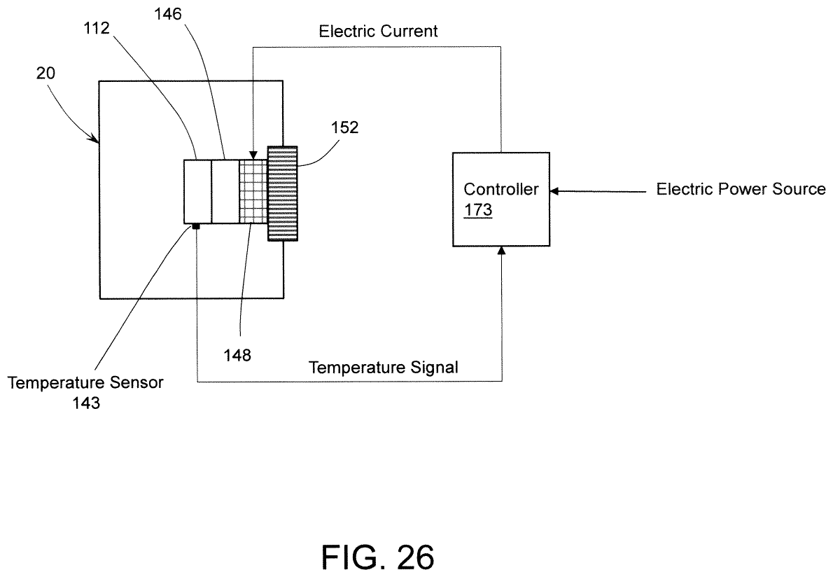

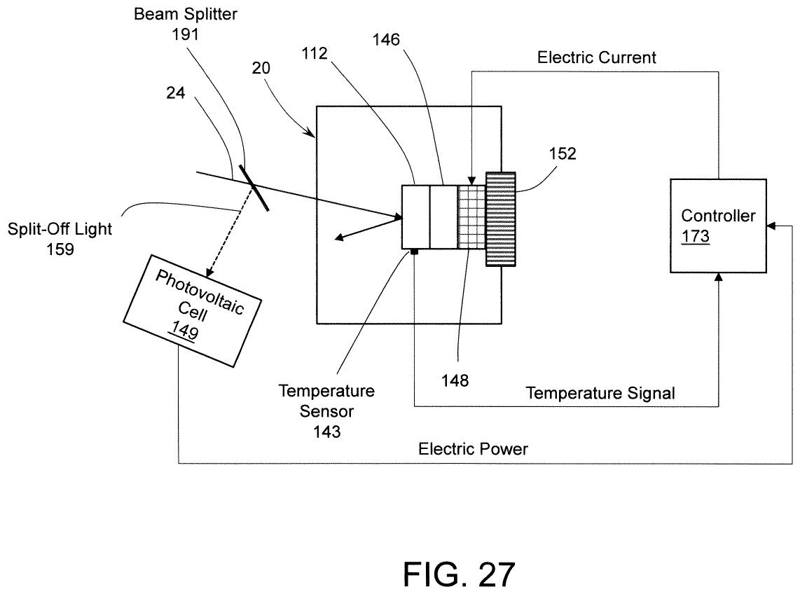

Referring now to FIG. 26, there is shown a schematic diagram for the temperature control loop for Faraday optics 112. The control loop uses a temperature sensor 143 such as a thermocouple or a thermistor that is in thermal communication with the Faraday optics 112 and sends a signal to a controller 173. The controller 173 correspondingly adjusts the drive power for the TEC 148 so that the temperature Faraday optics 112 closely corresponds to a predetermined temperature set point. The control loop may be operated by a battery or by an external source of electricity. In instance, where this is inconvenient, the electricity may be generated by photovoltaic action within the optical isolator. FIG. 27 is a schematic diagram showing how the control loop of FIG. 26 (including the TEC) may be operated by electricity generated by a photovoltaic cell 149 using a small portion 159 that is split-off by a beam splitter 191 from the incident laser light 24.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” and “includes” and/or “including” when used in this specification, specify the presence of stated features, integers, steps, operations, elements, and/or components, but do not preclude the presence or addition of one or more other features, integers, steps, operations, elements, components, and/or groups thereof.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

The term “suitable,” as used herein, means having characteristics that are sufficient to produce a desired result. Suitability for the intended purpose can be determined by one of ordinary skill in the art using only routine experimentation.

Moreover, terms that are expressed as “means-plus function” in the claims should include any structure that can be utilized to carry out the function of that part of the present invention. In addition, the term “configured” as used herein to describe a component, section or part of a device includes hardware and/or software that is constructed and/or programmed to carry out the desired function.

Different aspects of the invention may be combined in any suitable way.

While only selected embodiments have been chosen to illustrate the present invention, it will be apparent to those skilled in the art from this disclosure that various changes and modifications can be made herein without departing from the scope of the present invention as defined in the appended claims. Furthermore, the foregoing description of the embodiments according to the present invention are provided for illustration only, and not for the purpose of limiting the present invention as defined by the appended claims and their equivalents. Thus, the scope of the present invention is not limited to the disclosed embodiments.

Although the present invention has been shown and described in considerable detail with respect to only a few exemplary embodiments thereof, it should be understood by those skilled in the art that this is not intended to limit the invention to the embodiments since various modifications, omissions and additions may be made to the disclosed embodiments without materially departing from the novel teachings and advantages of the invention, particularly in light of the foregoing teachings. Accordingly, the claims are intended to cover all such modifications, omission, additions and equivalents as may be included within the spirit and scope of the invention as defined by the following claims. In the claims, means-plus-function clauses are intended to cover the structures described herein as performing the recited function and not only structural equivalents but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. An optical isolator comprising a Faraday rotator, a polarizing separator; and a halfwave plate;
a) Said Faraday rotator further comprising a Faraday optic, permanent magnet, thermally conductive member, and a heat sink;
b) Said Faraday optic having a transverse dimension “D” and thickness “L”;
c) Said dimension “L” arranged so that the polarization plane of a laser beam at a predetermined wavelength is rotated by 22.5 degrees upon entering traversing the distance “L” inside said Faraday optic;
d) Said Faraday optic comprising a first surface having an optical coating that is antireflective (AR) at said predetermined wavelength;
e) Said Faraday optic comprising a second surface having an optical coating that is highly reflective (HR) at said predetermined wavelength;
f) Said thermally conductive member providing a good thermal communication between second surface of said Faraday optic and said heat sink;
g) Said polarizing separator arranged for separation of an unpolarized input laser beam at said predetermined wavelength into an ordinary beam and an extraordinary beam; and
h) Said ordinary and an extraordinary beam being substantially coplanar in a first plane.

2. The optical isolator of claim 1, further including a first telescope arranged to expand said laser beam in a direction substantially perpendicular to said first plane.

3. The optical isolator of claim 2, further including a second telescope arranged to receive said laser beam expanded in said first telescope and compact it in a direction substantially perpendicular to said first plane to substantially reverse said expansion.

4. The optical isolator of claim 1, further including a thermoelectric cooler (TEC); said TEC being arranged to receive heat from said thermally conductive member and conveying it to said heat sink.

5. The optical isolator of claim 4, further including controls for said TEC arranged to maintain said Faraday optics at a predetermined temperature.

6. The optical isolator of claim 4, further including a photovoltaic cell arranged to converting a portion of said laser beam into electricity and supplying it to said TEC.

7. The optical isolator of claim 1, further including a fan arranged to direct a flow of ambient air onto said heat sink.

8. The optical isolator of claim 1, further including a heat pipe; said TEC being arranged to receive heat from said thermally conductive member and conveying it to said heat sink.

9. The optical isolator of claim 1, wherein said thermally conductive member is at least in part fabricated from a soft magnetic material.

10. An optical isolator comprising a Faraday rotator, first polarizing separator, second polarizing separator, half-wave plate, input optics assembly, and output optics assembly;
a) Said Faraday rotator further comprising a Faraday optic, permanent magnet, thermally conductive member, and a heat sink;
b) Said Faraday optic having a transverse dimension “D” and thickness “L”; and
c) Said dimension “L” arranged so that the polarization plane of a laser beam at a predetermined wavelength is rotated by 22.5 degrees upon entering traversing the distance “L” inside said Faraday optic.

11. The optical isolator of claim 10, wherein said input optics assembly further comprises a fiber connector, collimating optic, beam expanding telescope, and a light absorber.

12. The optical isolator of claim 11, wherein beam expanding telescope comprises an anamorphic prism pair.

13. The optical isolator of claim 10, wherein said output optics assembly further comprises a fiber connector, focusing optic, and a beam compacting telescope.

14. The optical isolator of claim 13, wherein beam compacting telescope comprises an anamorphic prism pair.

15. The optical isolator of claim 10, wherein said first polarizing separator comprises two right angle prisms, a parallelepiped, and thin film polarizing coatings.

16. The optical isolator of claim 10, wherein said first polarizing separator is arranged to receive an unpolarized input laser beam at said predetermined wavelength and separating it into an ordinary beam and an extraordinary beam.

17. An optical isolator comprising a Faraday rotator, half-wave plate, and a thermoelectric cooler (TEC);
a) Said Faraday rotator further comprising a Faraday optic, permanent magnet, thermally conductive member, and a heat sink; and
b) said TEC being arranged to receive heat from said thermally conductive member and conveying it to said heat sink.

18. The optical isolator of claim 17, further including controls for said TEC arranged to maintain said Faraday optics at a predetermined temperature.

19. The optical isolator of claim 18, further including a photovoltaic cell arranged to converting a portion of said laser beam into electricity and supplying it to said TEC.

20. The optical isolator of claim 17, further including a fan arranged to direct a flow of ambient air onto said heat sink.
